(19) United States
(12) Patent Application Publication
(10) Pub. No.: US 2019/0354362 A1
(43) Pub. Date: Nov. 21, 2019

(54) ON-BOARD UPDATE SYSTEM AND ON-BOARD UPDATE APPARATUS

(71) Applicants: AutoNetworks Technologies, Ltd., Yokkaichi, Mie (JP); Sumitomo Wiring Systems, Ltd., Yokkaichi, Mie (JP); Sumitomo Electric Industries, Ltd., Osaka-Shi (JP)

(72) Inventor: Takahiro Saito, Yokkaichi, Mie (JP)

(21) Appl. No.: 16/461,666

(22) PCT Filed: Nov. 10, 2017
(86) PCT No.: PCT/JP2017/040525

§ 371 Date: May 16, 2019

(30) Foreign Application Priority Data
Nov. 28, 2016 (JP) 2016-230495

(51) Int. Cl. G06F 8/65; B60R 16/033; B60Q 9/00; G01R 19/165

(52) U.S. Cl. CPC G06F 8/65; G01R 19/16576; B60Q 9/00; B60R 16/033

(57) ABSTRACT

An on-board update system according to the present embodiment includes: a battery that is installed in a vehicle; an on-board device configured to operate by receiving power from the battery and by executing a program stored in a storage unit; an on-board electronic component to which the power from the battery is supplied; a detection unit configured to detect the amount of current flowing through the on-board electronic component; an on-board update apparatus configured to perform a process for updating the program stored in the storage unit of the on-board device; and a notification unit configured to notify an occupant of the vehicle before the on-board update apparatus performs an update process, if the amount of current detected by the detection unit exceeds a threshold value. The on-board electronic component may be, for example, a cigarette lighter socket.

### CROSS-REFERENCE TO RELATED APPLICATIONS

This application is the U.S. national stage of PCT/JP2017/040525 filed Nov. 10, 2017, which claims priority of Japanese Patent Application No. JP 2016-230495 filed Nov. 28, 2016, the contents of which are incorporated herein.

### TECHNICAL FIELD

The present disclosure relates to an on-board update system and an on-board update apparatus for updating a program of an on-board device installed in a vehicle.

### BACKGROUND

A vehicle is conventionally equipped with a plurality of on-board devices such as ECUs (Electronic Control Units), which are connected via communication lines such as CAN (Controller Area Network) buses and thereby capable of transmitting and receiving information to and from each other. In each ECU that performs various processes such as the control of a vehicle, a processor including a CPU (Central Processing Unit) reads out and executes a program stored in a storage unit such as a flash memory or EEPROM (Electrically Erasable Programmable Read Only Memory). The program or data stored in the storage unit of each ECU needs to be updated with a new program or data, for example, when it is necessary to add a function, to correct a fault, to upgrade, etc. In this case, an update program or data is transmitted via a communication line to the ECU to be updated.

JP 2011-70287A discloses a program update system in which, when updating a program after the driver has exited a vehicle while its engine is running, a program update apparatus monitors the state of the vehicle and transmits the monitored state to a center, and the center monitors the state of the vehicle whose program is being updated.

In the program update system disclosed in JP 2011-70287A, a program is updated while the engine of a vehicle is running. However, there may be a case in which it is desired to update a program while the engine is stopped, during which the user is not likely to use the vehicle. If the program is updated while the engine is stopped, it is necessary to operate an ECU to be updated with power stored in the battery of the vehicle. For this reason, if the ECU to be updated is connected to the battery, for example, via a relay such as an IG (ignition) relay or an ACC (accessory) relay, control for switching the relay to a conductive state is performed when the program is updated.

By controlling the conduction of the relay in such a manner, power is supplied from the battery to ECUs that are not to be updated, other electronic components, or the like that are connected to that relay or a different relay interconnected with that relay. It is possible to stop the operations of the ECUs that are not to be updated by, for example, transmitting a stop operation command to these ECUs via an in-vehicle network. However, if an electronic component whose operation cannot be stopped in such a manner is present, there is a concern that this electronic component may consume power and exhaust the battery during the update process. If the electronic component is a connection portion, such as a cigarette lighter socket of the vehicle, to which the user can connect a device, it is difficult to estimate how much power will be consumed by the device connected to the connection portion.

The present disclosure has been made in view of such circumstances and an object thereof is to provide an on-board update system and on-board update apparatus that can prevent battery exhaustion due to performing an update process of an on-board device.

### SUMMARY

An on-board update system according to one aspect of the present disclosure includes: an on-board device configured to operate by receiving power supplied from a battery installed in a vehicle and by executing a program stored in a storage unit; an on-board update apparatus configured to perform a process for updating the program stored in the storage unit of the on-board device; and a notification unit configured to notify an occupant of the vehicle before the on-board update apparatus performs an update process, if an amount of current that is detected by a detection unit configured to detect an amount of current flowing through an on-board electronic component to which the power from the battery is supplied exceeds a threshold value.

The on-board update system according to one aspect of the present disclosure may further include a first relay that is arranged in a first power supply path from the battery to the on-board device, and is configured to switch the first power supply path between conduction and interruption, wherein the on-board update apparatus may be configured to switch the first relay to the conductive state if the on-board update apparatus performs an update process.

The on-board update system according to one aspect of the present disclosure may further include a second relay that is arranged in a second power supply path from the battery to the on-board electronic component, and that is configured to switch the second power supply path between conduction and interruption in conjunction with the first relay, wherein the detection unit may be configured to perform detection if the second relay is in the conductive state.

The on-board update system according to one aspect of the present disclosure may further include a second relay that is arranged in a second power supply path from the battery to the on-board electronic component, and is configured to switch the second power supply path between conduction and interruption in conjunction with the first relay, and a power storage unit configured to accumulate power if the second relay is in a conductive state, wherein, if the second relay is in the interrupted state and the detection unit performs detection, the power that the power storage unit accumulates may be supplied to the on-board electronic component.

In the on-board update system according to one aspect of the present disclosure, the on-board electronic component may be a connection portion to which a power supply line can be detachably connected.

In the on-board update system according to one aspect of the present disclosure, the connection portion may be a cigarette lighter socket.

In the on-board update system according to one aspect of the present disclosure, the on-board update apparatus may include an acquisition unit configured to acquire a detection result of the detection unit, and the notification unit.

The on-board update apparatus according to one aspect of the present disclosure is an on-board update apparatus configured to perform a process for updating a program stored in a storage unit of an on-board device that is configured to operate by receiving power supplied from a battery installed in a vehicle, the on-board update apparatus including: an acquisition unit configured to acquire a detection result from a detection unit configured to detect an amount of current flowing through an on-board electronic component installed in the vehicle; and a notification unit configured to perform a process relating to a notification for an occupant of the vehicle before an update process of the on-board device is performed, if the amount of current detected by the detection unit exceeds a threshold value.

According to one aspect of the present disclosure, the on-board update apparatus performs an update process of a program of the on-board device while the engine of the vehicle is stopped. Before the on-board update apparatus performs the update process, the amount of current flowing through an on-board electronic component that is not to be updated is detected. If the detected amount of current exceeds the threshold value, that is, if there is a possibility that power may be consumed due to a current flowing through the on-board electronic component, a notification is made for the occupant of the vehicle. In this manner, the occupant can recognize the presence of an on-board electronic component that may consume power when an update process is performed, and can previously take a measure, such as turning off such an on-board electronic component or removing such an on-board electronic component from the vehicle.

According one aspect of the present disclosure, the on-board update apparatus directly or indirectly switches the first relay, which is arranged in the first power supply path from the battery to the on-board device to be updated, between conduction and interruption. The on-board update apparatus switches the first relay to the conductive state when performing an update process and activates the on-board device by supplying power from the battery. As a result, even if the first relay is in the interrupted state while the engine of the vehicle is stopped, the on-board update apparatus can perform the update process of the on-board device by switching the first relay to the conductive state.

According to one aspect of the present disclosure, the second relay is arranged in the second power supply path from the battery to the on-board electronic component that is not to be updated, and the second relay is switched between conduction and interruption in conjunction with the first relay. In this configuration, the amount of current flowing through the on-board electronic component is detected if the second relay is in the conductive state. The notification to the occupant of the vehicle may be made if the second relay is in the conductive state or the interrupted state. A configuration may be employed, for example, in which the notification is made after the second relay was switched to the interrupted state (after the engine was stopped), depending on the amount of current flowing through the on-board electronic component, which was detected immediately before the second relay was switched from the conductive state to the interrupted state (immediately before the engine of the vehicle was stopped). In this manner, the amount of current flowing from the battery to the on-board electronic component can be accurately detected.

According to one aspect of the present disclosure, the amount of current flowing through the on-board electronic component may also be detected if the second relay is in the interrupted state. In this configuration, power is accumulated in the power storage unit if the second relay is in the conductive state. Then, the power accumulated in the power storage unit is supplied to the on-board electronic component after the second relay was switched to the interrupted state, and the amount of current flowing through the on-board electronic component at this time is detected. In this manner, even after the second relay was switched to the interrupted state (after the engine was stopped), it is possible to detect the amount of current flowing through the on-board electronic component.

According to one aspect of the present disclosure, the on-board electronic component, in which the current flowing therethrough is detected and notified, may be the connection portion to which the power supply line can be detachably connected, for example, may be a cigarette lighter socket. It is possible to determine whether an apparatus is connected to the connection portion by detecting the amount of current flowing through the connection portion. Accordingly, it is possible to notify the occupant of the vehicle that an apparatus that may cause battery exhaustion is connected.

According to one aspect of the present disclosure, the on-board update apparatus includes the acquisition unit for acquiring the detection result of the amount of current, and the notification unit for performing a process related to the notification to the occupant. If the notification is made by displaying a message on a display apparatus, for example, the notification unit of the on-board update apparatus provides a command for displaying a notification message to the display apparatus. With the configuration in which the on-board update apparatus acquires the detection result of the amount of current, determines the amount of current, and provides the notification, the configuration of the on-board update system can be simplified compared with a configuration in which these processes are performed by a plurality of apparatuses.

### Advantageous Effects of Disclosure

According to one aspect of the present disclosure, with the configuration in which the amount of current flowing from the battery of the vehicle to the on-board electronic component that is not to be updated is detected and notification is provided to the occupant of the vehicle if the amount of current exceeds the threshold value, the occupant of the vehicle can recognize that an on-board electronic component that may consume power when an update process is performed is present. Accordingly, a measure such as turning off that on-board electronic component or removing that on-board electronic component from the vehicle can be preemptively taken, which prevents battery exhaustion due to the update process of the on-board device.

### BRIEF DESCRIPTION OF DRAWINGS

FIG. 1 is a block diagram showing the configuration of an on-board update system according to a first embodiment.

FIG. 2 is a block diagram showing the configuration of an on-board update apparatus according to the present embodiment.

FIG. 3 is a flowchart showing a procedure of processes performed by the on-board update apparatus according to the present embodiment.

FIG. 4 is a flowchart showing a procedure of processes performed by the on-board update apparatus according to the present embodiment.

FIG. 5 is a flowchart showing a procedure of processes performed by an on-board update apparatus according to a variation.

FIG. 6 is a block diagram showing the configuration of a current detection unit of an on-board update system according to a second embodiment.

FIG. 7 is a flowchart showing a procedure of processes performed by an on-board update apparatus according to the second embodiment.

### DETAILED DESCRIPTION OF PREFERRED EMBODIMENTS

### First Embodiment

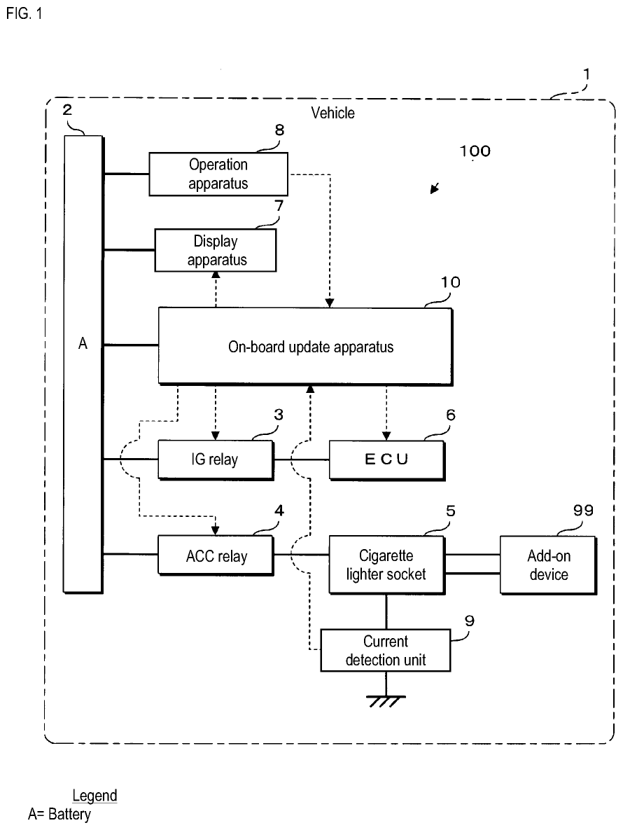

FIG. 1 is a block diagram showing the configuration of an on-board update system 100 according to a first embodiment. In this drawing, the bold solid lines represent power supply paths and the broken lines represent signal transmission paths. Also, reference numeral 1 represented by the alternate long and short dash line is a vehicle. The vehicle 1 includes a battery 2, an IG relay 3, an ACC relay 4, a cigarette lighter socket 5, an ECU 6, a display apparatus 7, and an operation apparatus 8. The battery 2 is an apparatus for accumulating power generated by an alternator (not shown) during the operation of the engine of the vehicle 1. The battery 2 can be configured using a battery such as a lead storage battery or a lithium ion battery. While the engine of the vehicle 1 is stopped, the battery 2 supplies the accumulated power to an on-board device such as the ECU 6 that is installed in the vehicle 1.

The IG relay 3 is arranged in a power supply path from the battery 2 to the on-board device such as the ECU 6, and switches the power supply path between conduction and interruption. Note, that only one ECU 6 is connected to the IG relay 3 in FIG. 1, but there is no limitation to this. A plurality of on-board devices may be connected to the IG relay 3. The IG relay 3 is switched between conduction and interruption, depending on the state of an ignition switch (not shown) for performing operations of starting the engine of the vehicle 1 and switching the power supply state to the on-board device. The IG relay 3 is switched to the conductive state during the operation of the engine of the vehicle 1, and is switched to the interrupted state during the stop of the engine.

The ACC relay 4 is arranged in a power supply path from the battery 2 to an on-board electronic component such as the cigarette lighter socket 5, and switches the power supply path between conduction and interruption. Note, that only the cigarette lighter socket 5 is connected to the ACC relay 4 in FIG. 1, but there is no limitation to this. An on-board device such as an ECU or another on-board electronic component may be further connected to the ACC relay 4. The ACC relay 4 is also switched between conduction and interruption depending on the state of the ignition switch of the vehicle 1. The switching of the IG relay 3 between conduction and interruption is performed in conjunction with the switching of the ACC relay 4 between conduction and interruption. If the IG relay 3 is in the conductive state, also the ACC relay 4 is in the conductive state. If the ACC relay 4 is in the interrupted state, also the IG relay 3 is in the interrupted state. Note, that there may be cases in which the IG relay 3 is in the interrupted state and the ACC relay 4 is in the conductive state.

The cigarette lighter socket 5 is a socket for a cigarette lighter, which is provided near the driver's seat of the vehicle 1. Note, that the cigarette lighter socket 5 is used not only for a cigarette lighter, but also as a connection portion for supplying power to the outside. In this case, the cigarette lighter socket 5 can be also called an accessory socket or a power socket. Various add-on devices 99 can be connected to the cigarette lighter socket 5 via a power source cable provided with a terminal, that is, a so-called car plug. If the ACC relay 4 is switched to the conductive state in a state where the add-on device 99 is connected to the cigarette lighter socket 5, power is supplied from the alternator or the battery 2 of the vehicle 1 to the add-on device 99. The add-on device 99 can operate with this power.

The ECU 6 may be any of various ECUs, such as an ECU that controls the operation of the engine of the vehicle 1, an ECU that controls the locking and unlocking of the doors of the vehicle 1, an ECU that controls the turning on and off of the lights of the vehicle 1, an ECU that controls the operation of the air bags of the vehicle 1, and an ECU that controls the operation of the ABS (Antilock Brake System) of the vehicle 1. The ECU 6 performs various processes by a CPU (Central Processing Unit) or the like executing a program stored in an internal memory or the like. The ECU 6 according to the present embodiment is an ECU that may be subject to an update process, which is performed for updating a program stored in a memory or the like, and is connected to the battery 2 via the IG relay 3.

The display apparatus 7 is, for example, a liquid crystal display, and displays messages or images to the user of the vehicle 1. The operation apparatus 8 is an apparatus such as a push-switch, a dial-switch, or a touch panel arranged near the driver's seat of the vehicle 1, and is an apparatus for receiving operations from the user. Note, that the display apparatus 7 and the operation apparatus 8 may also be used, for example, as units of a car navigation apparatus. In the present embodiment, a configuration is employed in which the display apparatus 7 and the operation apparatus 8 directly receive power from the battery 2, but there is no limitation to this. A configuration may also be employed, in which the display apparatus 7 and the operation apparatus 8 are connected to the battery 2 via the IG relay 3 or the ACC relay 4.

The on-board update system 100 according to the present embodiment includes an on-board update apparatus 10 and a current detection unit 9. The on-board update apparatus 10 is an apparatus that performs a process for updating a program or data (hereinafter, simply referred to as a program) that is stored in the memory or the like of the ECU 6. The on-board update apparatus 10 performs communication, for example, with a server apparatus installed outside the vehicle 1 during the operation of the engine of the vehicle 1, and inquires whether the program of the ECU 6 needs to be updated. If the update needs to be performed, the on-board update apparatus 10 downloads and stores an update program. When or before the engine of the vehicle 1 is stopped, the on-board update apparatus 10 displays a message for notifying that the program of the ECU 6 needs to be updated on the display apparatus 7, inquires whether to perform the update, and receives the selection as to whether to perform the update from the user through the operation apparatus 8. If permission for performing the update is obtained, the on-board update apparatus 10 performs an update process by transmitting the stored update program to the ECU 6 to be updated when a predetermined update timing has been reached, for example, when a predetermined time has elapsed after the engine of the vehicle 1 was stopped.

Note, that in the present embodiment, the ECU 6 to be updated is connected to the battery 2 via the IG relay 3. The IG relay 3 is in the interrupted state while the engine of the vehicle 1 is stopped. Therefore, power is not supplied from the battery 2 to the ECU 6, and thus the ECU 6 cannot operate. The on-board update apparatus 10 according to the present embodiment can control the switching of the IG relay 3 and the ACC relay 4. Accordingly, when the update process of the ECU 6 is performed, the ECU 6 to be updated can operate by switching the IG relay 3 to the conductive state.

Note, that as mentioned above, the IG relay 3 is switched in conjunction with the ACC relay 4. Thus, if the IG relay 3 is in the conductive state, the ACC relay 4 is also in the conductive state. If the on-board update apparatus 10 switches the IG relay 3 to the conductive state for updating the ECU 6, the ACC relay 4 is also switched to the conductive state. Accordingly, if the add-on device 99 is connected to the cigarette lighter socket 5, power is supplied from the battery 2 to the add-on device 99 when the on-board update apparatus 10 performs the update process. The add-on device 99 is an apparatus that is connected according to the user's preference or necessity. Accordingly, there is no need to operate the add-on device 99 for updating the ECU 6, and there is no need to supply power from the battery 2 to the add-on device 99.

Therefore, in the present embodiment, a current detection unit 9 for detecting a current flowing through the cigarette lighter socket 5 (a current flowing through the add-on device 99) is provided. The current detection unit 9 is provided, for example, in the current path from the cigarette lighter socket 5 to the ground potential (the body earth). The current detection unit 9 detects the amount of current that flows from the battery 2 to the add-on device 99 through the cigarette lighter socket 5, and then flows from the add-on device 99 to the ground potential through the cigarette lighter socket 5. The amount of current, which is a detection result of the current detection unit 9, is input to the on-board update apparatus 10. Note, that the current detection unit 9 may input, to the on-board update apparatus 10, digital data indicating the detected amount of current, or may also input, to the on-board update apparatus 10, an analog signal having an amplitude value corresponding to the detected amount of current.

The on-board update apparatus 10 periodically acquires the amount of current that is input from the current detection unit 9. If the detected amount of current exceeds a predetermined threshold value (e.g., zero amperes), the on-board update apparatus 10 can determine that the add-on device 99 is connected to the cigarette lighter socket 5. If the on-board update apparatus 10 determines that the add-on device 99 is connected to the cigarette lighter socket 5, as mentioned above, when the selection as to whether to perform the update from the user is received using the display apparatus 7 and the operation apparatus 8, the on-board update apparatus 10 notifies the user that the add-on device 99 is connected to the cigarette lighter socket 5 by displaying a message on the display apparatus 7. Also, the on-board update apparatus 10 causes the display apparatus 7 to display a message for prompting removal of the add-on device 99 from the cigarette lighter socket 5.

In a configuration in which a message is displayed on the display apparatus 7 during the operation of the engine of the vehicle 1, a configuration may also be employed in which the on-board update apparatus 10 repeatedly acquires the detection result of the current detection unit 9 while the message is displayed, and does not accept an user operation for permitting the update process until the on-board update apparatus 10 determines that the add-on device 99 has been removed from the cigarette lighter socket 5. On the other hand, in a configuration in which a message is displayed during the stop of the engine of the vehicle 1, the on-board update apparatus 10 may determine whether the add-on device 99 is connected to the cigarette lighter socket 5 based on the detection result acquired from the current detection unit 9 immediately before the stop of the engine of the vehicle 1.

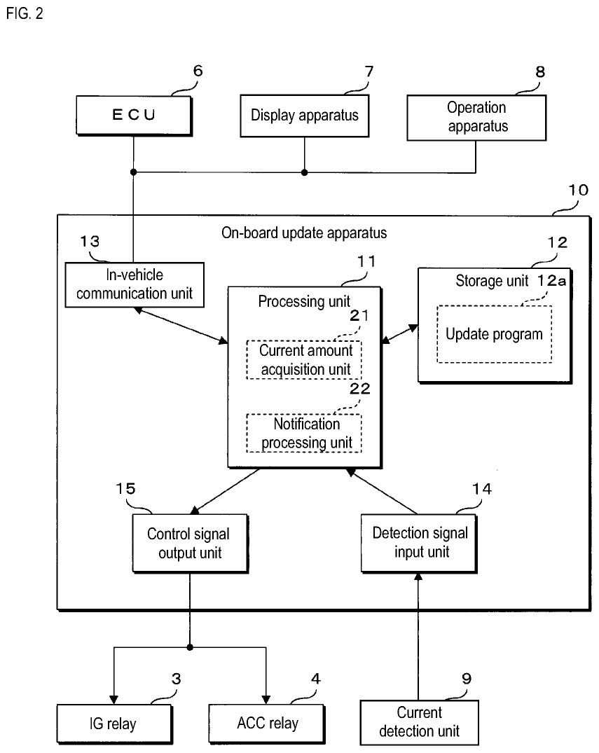

FIG. 2 is a block diagram showing the configuration of the on-board update apparatus 10 according to the present embodiment. The on-board update apparatus 10 according to the present embodiment includes a processing unit 11, a storage unit 12, an in-vehicle communication unit 13, a detection signal input unit 14, and a control signal output unit 15. The processing unit 11 is configured, for example, using a computation processing unit such as a CPU (Central Processing Unit) or an MPU (Micro-Processing Unit). The processing unit 11 performs various computations by reading out and executing a program (not shown) stored in the storage unit 12. The processing unit 11 performs processes such as a process for downloading an update program of the ECU 6 from the server apparatus installed outside the vehicle, a process for inquiring whether to perform an update process to the user, and a process for updating a program by transmitting the downloaded update program to the ECU 6. Also, the processing unit 11 according to the present embodiment performs processes such as a process for switching control of the IG relay 3 and the ACC relay 4 when an update process is performed, and a process for performing a notification based on a detection result of the current detection unit 9.

The storage unit 12 is configured using a non-volatile memory device such as a flash memory or EEPROM (Electrically Erasable Programmable Read Only Memory). The storage unit 12 stores, for example, programs executed by the processing unit 11 and data necessary for executing these programs, and also stores an update program 12a used for updating the ECU 6. The storage unit 12 may also store data generated during the processing in the processing unit 11.

The in-vehicle communication unit 13 is connected to the communication line that constitutes the in-vehicle network provided in the vehicle 1, and transmits and receives data in accordance with, for example, a communication protocol such as CAN. To transmit information, the in-vehicle communication unit 13 converts the data provided from the processing unit 11 into an electric signal, and outputs the electric signal to the communication line. To receive data, the in-vehicle communication unit 13 samples an electrical potential at the communication line, and provides the received data to the processing unit 11.

The detection signal input unit 14 is connected to the current detection unit 9 via the signal line or the like, and receives a signal indicating the detection result of the amount of current, which is output from the current detection unit 9. If the detection signal input unit 14 receives the detection result as a digital signal, the detection signal input unit 14 may provide the received detection result to the processing unit 11 as digital data. If the detection signal input unit 14 receives the detection result as an analog signal, the detection signal input unit 14 converts the analog signal to digital data by acquiring the received analog signal through sampling, and provides the detection result that is converted to the digital data to the processing unit 11.

The control signal output unit 15 is connected to the IG relay 3 and the ACC relay 4 via the signal line or the like, and outputs a control signal for switching these relays between conduction and interruption depending on the instruction from the processing unit 11. Note, that in the present embodiment, a configuration is employed in which the on-board update apparatus 10 directly controls the switching of the relays, but there is no limitation to this. A configuration may also be employed in which an ECU for controlling the switching of the relays is separately provided, and the on-board update apparatus 10 instructs the switching of the relays to this ECU. Also in the present embodiment, the switching control of the relays depending on the operation of the ignition switch of the vehicle is not performed by the on-board update apparatus 10, but performed by another ECU (not shown) for controlling the switching of the relays.

In the processing unit 11, a current amount acquisition unit 21 and a notification processing unit 22 can be realized as software-like function blocks by the program stored in the storage unit 12 being executed. The current amount acquisition unit 21 periodically acquires a detection result corresponding to a signal that is input from the current detection unit 9 to the detection signal input unit 14, that is, the amount of current flowing through the cigarette lighter socket 5, and stores the acquired amount of current in the storage unit 12, the memory in the processing unit 11, or the like. At this time, the on-board update apparatus 10 may store at least the latest detection result of the amount of current, and may delete any detection results older than that from the memory.

The notification processing unit 22 determines whether the amount of current, which is acquired and stored by the current amount acquisition unit 21, exceeds the predetermined threshold value. If the acquired and stored amount of current exceeds the threshold value, the notification processing unit 22 displays a notification message on the display apparatus 7 by providing an instruction for displaying a notification message to the display apparatus 7 through the in-vehicle communication unit 13. In the present embodiment, it is determined whether the add-on device 99 is connected to the cigarette lighter socket 5 by comparing the amount of current with the threshold value. For this reason, the threshold value that is compared with the amount of current may be zero or a value close to zero. The threshold value is previously determined at the design stage or the like of the system in consideration of the influences by the detection error of the current detection unit 9, noises, and the like. The notification message may be a message, such as “Device is connected to cigarette lighter socket. For performing update process, remove device from cigarette lighter socket.”. It is preferable that the notification message informs the user that the add-on device 99 is connected to the cigarette lighter socket 5, and prompts the user to remove the add-on device 99 from the cigarette lighter socket 5.

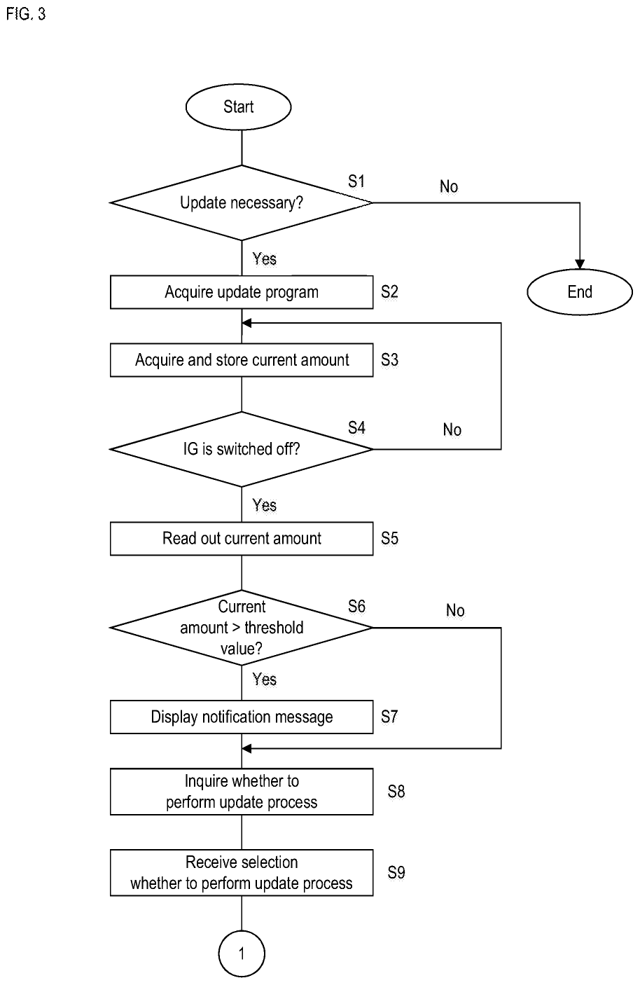

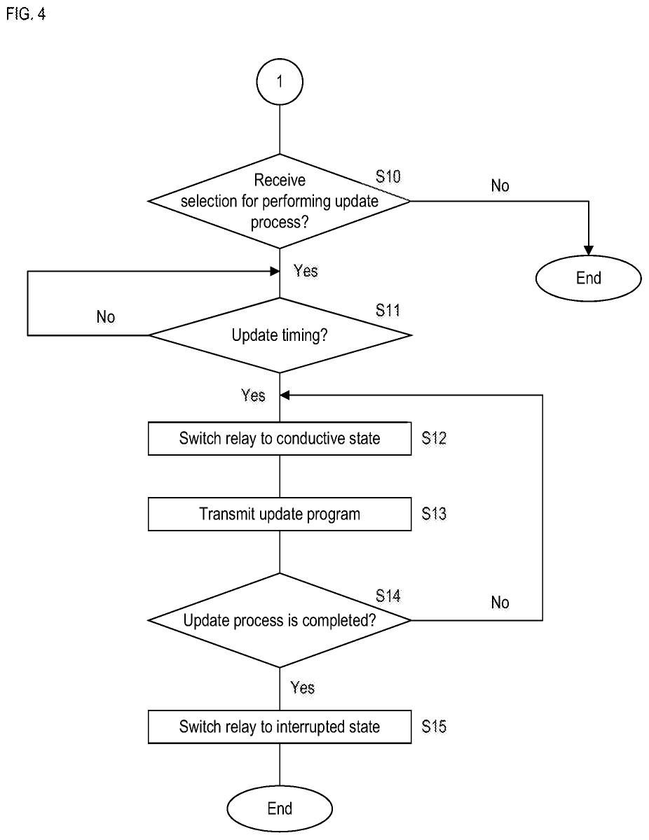

FIGS. 3 and 4 are flowcharts showing a procedure of processes performed by the on-board update apparatus 10 according to the present embodiment. The processes shown in the flowcharts start from a state in which the ignition switch of the vehicle 1 is on (that is, from a state in which the engine of the vehicle 1 is operating). In this state, both the IG relay 3 and ACC relay 4 of the vehicle 1 are in the conductive state. The processing unit 11 of the on-board update apparatus 10 performs, for example, wireless communication with the server apparatus installed outside the vehicle using a wireless communication apparatus that is installed in the vehicle 1. Then, the processing unit 11 determines whether an update process of the ECU 6 needs to be performed by inquiring, to the server apparatus, the presence or absence of an update of the program of the ECU 6 that is installed in the vehicle 1 (step S1). If no update process needs to be performed (NO in step S1), the processing unit 11 ends the process. If an update process needs to be performed (YES in step S1), the processing unit 11 acquires an update program necessary for performing the update process from the server apparatus (step S2), and stores the acquired update program in the storage unit 12.

Next, the current amount acquisition unit 21 of the processing unit 11 acquires the amount of current flowing through the cigarette lighter socket 5, which is detected by the current detection unit 9, and stores the acquired amount of current in the storage unit 12 (step S3). The processing unit 11 determines whether the ignition switch of the vehicle 1 is switched from the on state to the off state (step S4). If the ignition switch is in the on state, not being switched to the off state (NO in step S4), the processing unit 11 returns the process to step S3, and periodically acquires and stores the amount of current. If the ignition switch is switched from the on state to the off state (YES in step S4), the processing unit 11 reads out the amount of current that is stored in the storage unit 12 in step S3 (step S5).

The processing unit 11 determines whether the amount of current that is read out in step S5 exceeds the predetermined threshold vale (step S6). If the read-out amount of current exceeds the threshold value (YES in step S6), the notification processing unit 22 of the processing unit 11 displays a notification message for notifying that the add-on device 99 is connected to the cigarette lighter socket 5 (step S7), by providing an instruction for displaying a notification message to the display apparatus 7 through the in-vehicle communication unit 13. Then, the processing unit 11 moves the process to step S8. If the read-out amount of current does not exceed the threshold value (NO in step S6), the processing unit 11 displays no notification message, and moves the process to step S8.

Next, the processing unit 11 provides an instruction for displaying an inquiry message to the display apparatus 7 through the in-vehicle communication unit 13, and displays a message for inquiring whether to perform an update process of the ECU 6 on the display apparatus 7 for inquiring of the user whether to perform the update process (step S8). The message displayed at this time may be a message, such as “Program of ECU needs to be updated. Start updating today at 11 p.m.? (YES/NO)”. The processing unit 11 receives, through the operation apparatus 8, the selection as to whether to perform the update process from the user on the message displayed on the display apparatus 7 (step S9). The selection as to whether to perform the update process, which is received by the operation apparatus 8, is transmitted to the on-board update apparatus 10 via the in-vehicle network. Then, this selection is received by the in-vehicle communication unit 13 and provided to the processing unit 11.

The processing unit 11 determines whether permission for performing the update process of the ECU 6 is obtained, based on the selection that is received in step S9 (step S10). If permission for performing the update process is not obtained (NO in step S10), the processing unit 11 performs no update process, and ends the process. If permission for performing the update process is obtained (YES in step S10), the processing unit 11 determines whether the time for performing the update process has been reached (step S11). As a predetermined update timing, it is possible to employ timings, such as a predetermined time (e.g., 11 p.m.), or after two hours have elapsed after the ignition switch was switched to the off state. A configuration may also be employed, in which the user can decide this update timing. If the update timing has not been reached (NO in step S11), the processing unit 11 waits until the update timing is reached.

If the update timing has been reached (YES in step S11), the processing unit 11 switches the IG relay 3 to the conductive state (step S12). At this time, the ACC relay 4 is also switched to the conductive state. The processing unit 11 performs the update process by reading out the update program 12a stored in the storage unit 12 and transmitting the read-out update program to the ECU 6 to be updated through the in-vehicle communication unit 13 (step S13). The processing unit 11 determines whether the update program 12a has been transmitted and the update process of the ECU 6 has been completed (step S14). If the update process has not been completed (NO in step S14), the processing unit 11 returns the process to step S13, and continuously transmits the update program 12a. If the update process has been completed (YES in step S14), the processing unit 11 switches the IG relay 3 to the interrupted state (step S15), and ends the process.

In the on-board update system 100 according to the present disclosure having the above-mentioned configuration, the on-board update apparatus 10 performs an update process of the program of the ECU 6 while the engine of the vehicle 1 is stopped. The current detection unit 9 detects the amount of current flowing through the cigarette lighter socket 5, which is an on-board electronic component that is not to be updated, before the on-board update apparatus 10 performs an update process. If the detected current value exceeds the threshold value, that is, if there is a possibility that power may be consumed by the add-on device 99 being connected to the cigarette lighter socket 5, the on-board update apparatus 10 provides a notification to the user of the vehicle 1 by displaying a notification message on the display apparatus 7. In this manner, the user can recognize the presence of the add-on device 99 that may consume power when an update process of the ECU 6 is performed, and can previously take a measure such as removing this add-on device 99.

The on-board update apparatus 10 controls the switching of the IG relay 3, which is arranged in the power supply path from the battery 2 to the ECU 6 to be updated, between conduction and interruption. The on-board update apparatus 10 switches the IG relay 3 to the conductive state when performing an update process, and supplies power from the battery 2 to the ECU 6 to be updated to operate this ECU 6. Accordingly, even if the IG relay 3 is in the interrupted state during the stop of the engine of the vehicle 1, the on-board update apparatus 10 can perform the update process of the ECU 6 by switching the IG relay 3 to the conductive state.

In the on-board update system 100 according to the present disclosure, the ACC relay 4 is arranged in the power supply path from the battery 2 to the cigarette lighter socket 5 that is not to be updated. The ACC relay 4 is switched between conduction and interruption in conjunction with the IG relay 3. In this configuration, the amount of current flowing through the cigarette lighter socket 5 is detected if the ACC relay 4 is in the conductive state. Accordingly, it is possible to accurately detect the amount of current flowing from the battery 2 to the cigarette lighter socket 5 by the current detection unit 9. The notification to the user of the vehicle 1 may be performed if the ACC relay 4 is in the conductive state or the interrupted state. A configuration may be employed, for example, in which the notification is performed after the ACC relay 4 was switched to the interrupted state (after the engine was stopped) depending on the amount of current, which is detected by the current detection unit 9 immediately before the ACC relay 4 was switched from the conductive state to the interrupted state (immediately before the engine of the vehicle 1 was stopped).

In the on-board update system 100 according to the present embodiment, an on-board electronic component in which the current flowing therethrough is detected and notified may be, for example, the cigarette lighter socket 5, which serves as a connection portion to which the add-on device 99 can be detachably connected via the power supply line or the like. It is possible to detect whether the add-on device 99 is connected to the cigarette lighter socket 5 by detecting the amount of current flowing through the cigarette lighter socket 5. Accordingly, it is possible to notify the user of the vehicle 1 that the add-on device 99 that may exhaust the battery is connected.

Note, that in the present embodiment, a configuration is employed in which the dedicated on-board update apparatus 10 is provided in the system as an apparatus for performing an update process of the program of the ECU 6, but there is no limitation to this. A configuration may be employed in which a gateway apparatus, any ECU, or the like, which is installed in the vehicle 1, performs an update process. Also, the on-board update apparatus 10 may have a configuration in which, if another ECU is connected in the power supply path from the battery 2 to the ECU 6, the on-board update apparatus 10 transmits an operation stop command or the like to this ECU, which is not to be updated, in order to reduce power consumption when performing an update process.

The on-board update apparatus 10 according to the present disclosure has a configuration in which the on-board update apparatus 10 inquires of the user of the vehicle 1 whether to perform an update process before performing the update process, but there is no limitation to this. The on-board update apparatus 10 may also have a configuration, for example, in which the on-board update apparatus 10 performs an update process when an update timing is reached, without inquiring whether to perform the update process. Note, that also in this configuration, the on-board update apparatus 10 performs processes, at any timing before performing an update process, such as a process for determining whether the amount of current flowing through the cigarette lighter socket 5 exceeds the predetermined threshold and a process for displaying a notification message based on the determination result. The on-board update apparatus 10 may also have a configuration, for example, in which the on-board update apparatus 10 inquires whether to perform an update process if the amount of current flowing through the cigarette lighter socket 5 exceeds the threshold value, and performs an update process without inquiring whether to perform the update process if the amount of current does not exceed the threshold value.

The system configuration shown in FIG. 1 is an example, and there is no limitation to this. The ECU 6 to be updated may also be connected to the battery 2 via the ACC relay 4 instead of being connected to the battery 2 via the IG relay 3, for example. Also, the cigarette lighter socket 5 may also be connected to the battery 2 via the IG relay 3 instead of being connected to the battery 2 via the ACC relay 4, for example. A configuration is employed in which the current detection unit 9 is arranged in the current path from the cigarette lighter socket 5 to the ground potential, but there is no limitation to this. A configuration may also be employed in which the current detection unit 9 is arranged in the current path from the ACC relay 4 to the cigarette lighter socket 5.

In the present embodiment, the on-board electronic component subject to current detection by the current detection unit 9 is the cigarette lighter socket 5, but there is no limitation to this. The on-board electronic component may also be a USB (Universal Serial Bus) standard connection portion to which the add-on device 99 is detachably connected via a USB cable, for example, and that supplies power via the USB cable. The on-board electronic component may also be a connection portion having a configuration other than the cigarette lighter socket 5 and a USB standard connection portion. Furthermore, the on-board electronic component is not limited to a connection portion to which the add-on device 99 is connected. The on-board electronic component may also be an on-board apparatus, for example, in which the user of the vehicle 1 can directly control its power on/off by switching operation or the like, but to which the on-board update apparatus 10 cannot provide an operation stop command or the like through the in-vehicle communication or the like. In this case, a notification message may prompt the user to turn off the power of the apparatus.

### Variation

The on-board update system 100 according to the above-mentioned embodiment has a configuration in which a notification message is displayed on the display apparatus 7 if the amount of current flowing through the cigarette lighter socket 5 exceeds the threshold value, but there is no limitation to this. The on-board update system 100 according to a variation has a configuration in which performing an update process is prohibited if the amount of current flowing through the cigarette lighter socket 5 exceeds the threshold value. The on-board update apparatus 10 first displays a notification message on the display apparatus 7 if the on-board apparatus 10 determines that the amount of current flowing through the cigarette lighter socket 5 exceeds the threshold value. The current detection unit 9 repeatedly detects the amount of current in a state where the notification message is displayed. Also, the on-board update apparatus 10 acquires the detection results of the current detection unit 9, and repeatedly compares the amount of current with the threshold value. Then, if the comparison result shows that the amount of current does not exceed the threshold value, that is, if the add-on device 99 connected to the cigarette lighter socket 5 is removed, the on-board update apparatus 10 inquires whether to perform an update process, and receives the selection as to whether to perform the update process from the user. Then, the on-board update apparatus 10 performs the update process if permission for performing the update process is obtained. That is to say, the on-board update apparatus 10 according to the variation has a configuration in which performing an update process is prohibited by prohibiting an inquiry as to whether to perform the update process if the amount of current that is detected by the current detection unit 9 exceeds the threshold value. Note, that the method for prohibiting performing an update process is not limited to this, and another method may also be employed.

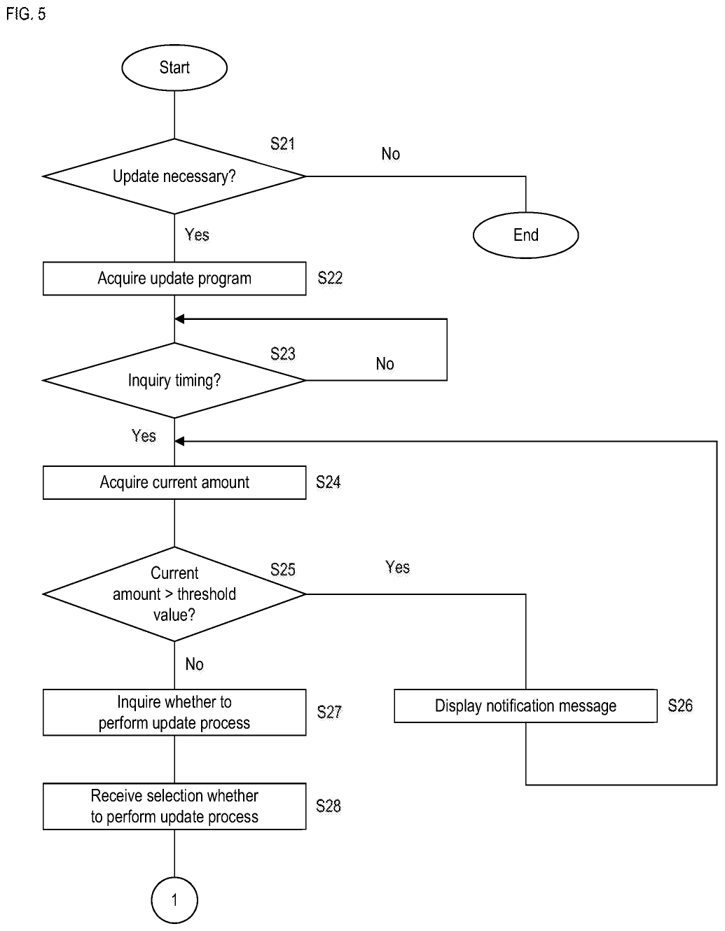

FIG. 5 is a flowchart showing a procedure of processes performed by the on-board update apparatus 10 according to this variation. Note, that the flowchart shown in FIG. 5 replaces the flowchart shown in FIG. 3. The processes shown in FIG. 4 may be performed following step S28 of the flowchart shown in FIG. 5. Accordingly, in the variation, illustrations and descriptions of processes similar to those shown in FIG. 4 will be omitted.

The processing unit 11 of the on-board update apparatus 10 according to the variation determines whether an update process of the ECU 6 needs to be performed (step S21). If no update process needs to be performed (NO in step S21), the processing unit ends the process. If an update process needs to be performed (YES in step S21), the processing unit 11 acquires an update program necessary for performing the update process from the server apparatus (step S22), and stores the acquired update program in the storage unit 12. Then, the processing unit 11 determines whether a timing for inquiring whether to perform the update process has been reached (step S23). The inquiry timing may be any timing from when the acquisition of the update program is completed to when the ignition switch of the vehicle 1 is switched to the off state. As the inquiry timing, for example, a timing may be employed at which the running speed of the vehicle 1 becomes 0 km/h for the first time after the acquisition of the update program is completed.

If the inquiry timing has not been reached (NO in step S23), the processing unit 11 waits until the inquiry timing is reached. If the inquiry timing has been reached (YES in step S23), the current amount acquisition unit 21 of the processing unit 11 acquires the amount of current flowing through the cigarette lighter socket 5, which is detected by the current detection unit 9 (step S24). The processing unit 11 determines whether the acquired amount of current exceeds the predetermined threshold value (step S25). If the acquired amount of current exceeds the threshold value (YES in step S25), the notification processing unit 22 of the processing unit 11 displays, on the display apparatus 7, a message for notifying that the add-on device 99 is connected to the cigarette lighter socket 5 (step S26) by providing an instruction for displaying a notification message to the display apparatus 7 through the in-vehicle communication unit 13. Then, the processing unit 11 returns the process to step S24.

If the acquired amount of current does not exceed the threshold value (NO in step S25), the processing unit 11 displays, on the display apparatus 7, a message for inquiring whether to perform an update process of the ECU 6 by providing an instruction for displaying an inquiry message to the display apparatus 7 through the in-vehicle communication unit 13, and inquires of the user whether to perform the update process (step S27). The processing unit 11 receives, through the operation apparatus 8, the selection as to whether to perform the update process from the user on the message displayed on the display apparatus 7 (step S28), and moves the process to step S10.

### Second Embodiment

The on-board update system 100 according to the first embodiment has a configuration in which the current detection unit 9 detects the amount of current flowing through the cigarette lighter socket 5 if the engine of the vehicle 1 operates and the ACC relay 4 is in the conductive state, and the on-board update apparatus 10 stores the detection results and performs determination based on the stored detection results after the engine of the vehicle 1 is stopped and the ACC relay 4 is switched to the interrupted state. On the other hand, an on-board update system 100 according to a second embodiment has a configuration in which the current detection unit 9 can detect the amount of current flowing through the cigarette lighter socket 5 after the engine of the vehicle 1 is stopped and the ACC relay 4 is switched to the interrupted state.

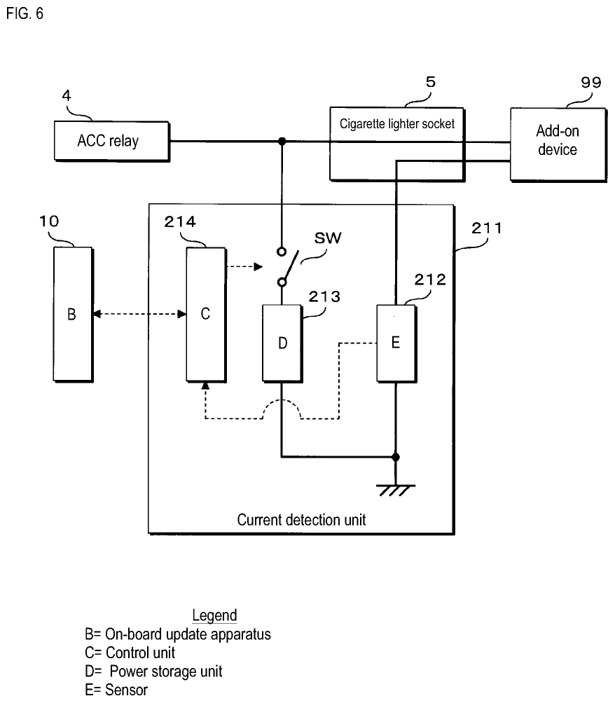

FIG. 6 is a block diagram showing the configuration of a current detection unit 211 of the on-board update system 100 according to the second embodiment. The current detection unit 211 according to the second embodiment includes a sensor 212, a power storage unit 213, a control unit 214, and a switch SW. The sensor 212 is provided in the current path from the cigarette lighter socket 5 to the ground potential. The sensor 212 detects the amount of current that flows from the battery 2 to the add-on device 99 through the ACC relay 4 and the cigarette lighter socket 5, and then flows from the add-on device 99 to the ground potential through the cigarette lighter socket 5. The sensor 212 provides, to the control unit 214, an analog signal having an amplitude value corresponding to the detected amount of current.

The power storage unit 213 is connected to the power supply path between the ACC relay 4 and the cigarette lighter socket 5 via the switch SW. The power storage unit 213 is configured, for example, using a rechargeable battery, a capacitor, or the like. The power storage unit 213 can accumulate power, and can supply the accumulated power to the outside. If the ACC relay 4 is in the conductive state and the switch SW is in the conductive state, power from the battery 2 or the alternator of the vehicle 1 is supplied to the power storage unit 213, and the power is accumulated in the power storage unit 213. If the ACC relay 4 is in the interrupted state and the switch SW is in the interrupted state, the power storage unit 213 keeps the accumulated power.

If the ACC relay 4 is in the interrupted state and the switch SW is in the conductive state, the power storage unit 213 can supply the accumulated power to the add-on device 99 that is connected to the cigarette lighter socket 5. In this state, the current flowing from the power storage unit 213 to the add-on device 99 via the cigarette lighter socket 5 flows from the add-on device 99 to the cigarette lighter socket 5, and then flows to the ground potential. The amount of this current is detected by the sensor 212.

The control unit 214 is configured, for example, using an IC such as a microcontroller. The control unit 214 transmits and receives signals to and from the on-board update apparatus 10, and controls the switching of the switch SW between conduction and interruption in response to an instruction from the on-board update apparatus 10. Also, the control unit 214 samples and acquires signals output from the sensor 212, and provides the detection result of the current value acquired through sampling to the on-board update apparatus 10.

The on-board update apparatus 10 according to the second embodiment performs the current detection by the current detection unit 211, after the ignition switch of the vehicle 1 is switched to the off state and the ACC relay 4 is switched to the interrupted state. The on-board update apparatus 10 provides, to the control unit 214 of the current detection unit 211, the instruction for switching the switch SW to the conductive state. The on-board update apparatus 10 also acquires the amount of current, which is detected by the sensor 212 at this time, from the control unit 214. If the acquired amount of current exceeds the threshold value, the on-board update apparatus 10 determines that the add-on device 99 is connected to the cigarette lighter socket 5, and displays a notification message on the display apparatus 7.

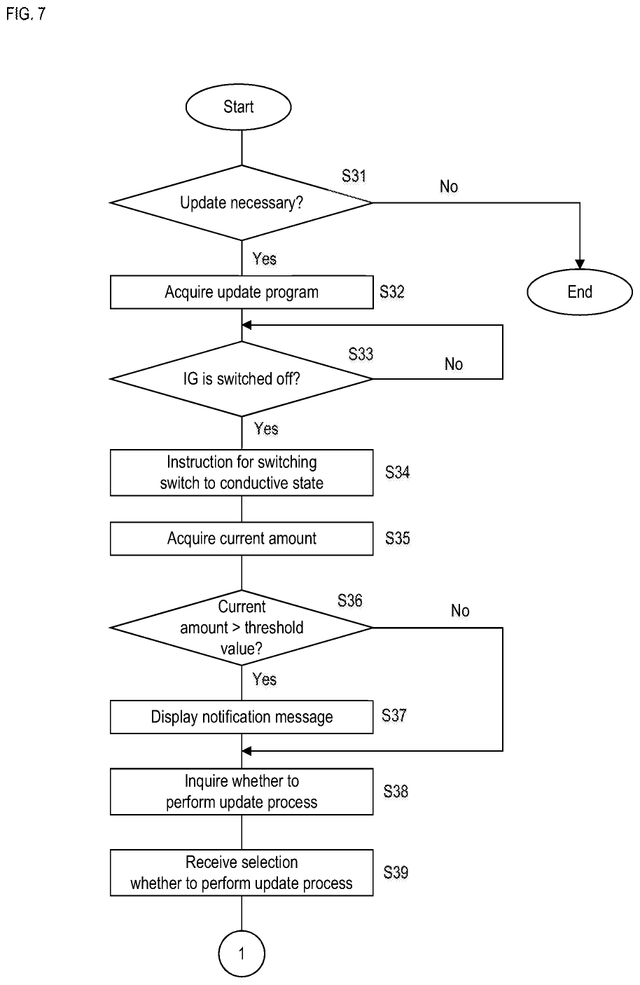

FIG. 7 is a flowchart showing a procedure of processes performed by the on-board update apparatus 10 according to the second embodiment. Note, that the flowchart shown in FIG. 7 replaces the flowchart shown in FIG. 3. The processes shown in FIG. 4 may be performed following step S39 of the flowchart shown in FIG. 7. Accordingly, in the second embodiment, illustrations and descriptions of the processes similar to those of the flowchart shown in FIG. 4 will be omitted.

The processing unit 11 of the on-board update apparatus 10 according to the second embodiment determines whether the ECU 6 needs to be updated (step S31). If no update process needs to be performed (NO in step S31), the processing unit 11 ends the process. If an update process needs to be performed (YES in step S31), the processing unit 11 acquires an update program necessary for performing the update process from the server apparatus (step S32), and stores the acquired update program in the storage unit 12. Then, the processing unit 11 determines whether the ignition switch of the vehicle 1 is switched from the on state to the off state (step S33). If the ignition switch is not switched to the off state (NO in step S33), the processing unit 11 waits until the ignition switch is switched to the off state.

If the ignition switch is switched from the on state to the off state (YES in step S33), the current amount acquisition unit 21 of the processing unit 11 provides, to the control unit 214, an instruction for switching the switch SW of the current detection unit 211 to the conductive state. The current amount acquisition unit 21 acquires the amount of current flowing through the cigarette lighter socket 5, which is detected by the sensor 212 of the current detection unit 211 (step S35). The processing unit 11 determines whether the acquired amount of current exceeds a predetermined threshold value (step S36). If the acquired amount of current exceeds the threshold value (YES in step S36), the notification processing unit 22 of the processing unit 11 displays, on the display apparatus 7, a message for notifying that the add-on device 99 is connected to the cigarette lighter socket 5 (step S37) by providing an instruction for displaying a notification message to the display apparatus 7 through the in-vehicle communication unit 13. Then, the processing unit 11 moves the process to step S38. If the acquired amount of current does not exceed the threshold value (NO in step S36), the processing unit 11 moves the process to step S38 without displaying a notification message.

Next, the processing unit 11 provides an instruction for displaying an inquiry message to the display apparatus 7 through the in-vehicle communication unit 13, and displays a message for inquiring whether to perform an update process of the ECU 6 on the display apparatus 7 for inquiring of the user whether to perform the update process (step S38). The processing unit 11 receives, through the operation apparatus 8, the selection as to whether to perform the update process from the user on the message displayed on the display apparatus 7 (step S39), and moves the process to step S10.

In the on-board update system 100 according to the second embodiment having the above configuration, power is stored in the power storage unit 213 of the current detection unit 211 if the ACC relay 4 is in the conductive state, the power accumulated in the power storage unit 213 is supplied to the cigarette lighter socket 5 after the ACC relay 4 is switched to the interrupted state, and the sensor 212 detects the current flowing through the add-on device 99 that is connected to the cigarette lighter socket 5. With this configuration, the on-board update apparatus 10 can detect the amount of current flowing through the cigarette lighter socket 5, even after the engine of the vehicle 1 is stopped and the ACC relay 4 is switched to the interrupted state.

Note, that because other configurations of the on-board update system 100 according to the second embodiment are the same as those of the on-board update system 100 according to the first embodiment, the same numerals are given to the same units and detailed descriptions thereof will be omitted.

1. An on-board update system, comprising:
an on-board device configured to operate by receiving power supplied from a battery installed in a vehicle, and by executing a program stored in a storage unit;
an on-board update apparatus configured to perform a process for updating the program stored in the storage unit of the on-board device; and
a notification unit configured to notify an occupant of the vehicle before the on-board update apparatus performs an update process, if an amount of current that is detected by a detection unit configured to detect an amount of current flowing through an on-board electronic component to which the power from the battery is supplied exceeds a threshold value.

2. The on-board update system according to claim 1, further comprising:
a first relay that is arranged in a first power supply path from the battery to the on-board device, and is configured to switch the first power supply path between conduction and interruption,
wherein the on-board update apparatus is configured to switch the first relay to the conductive state if the on-board update apparatus performs an update process.

3. The on-board update system according to claim 2, further comprising:
a second relay that is arranged in a second power supply path from the battery to the on-board electronic component, and that is configured to switch the second power supply path between conduction and interruption in conjunction with the first relay,
wherein, the detection unit is configured to perform detection if the second relay is in the conductive state.

4. The on-board update system according to claim 2, further comprising:
a second relay that is arranged in a second power supply path from the battery to the on-board electronic component, and is configured to switch the second power supply path between conduction and interruption in conjunction with the first relay; and
a power storage unit configured to accumulate power if the second relay is in the conductive state,
wherein, if the second relay is in the interrupted state and the detection unit performs detection, the power that the power storage unit accumulates is supplied to the on-board electronic component.

5. The on-board update system according to claim 1, wherein
the on-board electronic component is a connection portion to which a power supply line can be detachably connected.

6. The on-board update system according to claim 5, wherein
the connection portion is a cigarette lighter socket.

7. The on-board update system according to claim 1, wherein
the on-board update apparatus includes an acquisition unit configured to acquire a detection result of the detection unit, and the notification unit.

8. An on-board update apparatus configured to perform a process for updating a program stored in a storage unit of an on-board device that is configured to operate by receiving power supplied from a battery installed in a vehicle, the on-board update apparatus comprising:
an acquisition unit configured to acquire a detection result from a detection unit configured to detect an amount of current flowing through an on-board electronic component installed in the vehicle; and
a notification unit configured to perform a process relating to a notification for an occupant of the vehicle before an update process of the on-board device is performed, if the amount of current detected by the detection unit exceeds a threshold value.

9. The on-board update system according to claim 2, wherein the on-board electronic component is a connection portion to which a power supply line can be detachably connected.

10. The on-board update system according to claim 3, wherein the on-board electronic component is a connection portion to which a power supply line can be detachably connected.

11. The on-board update system according to claim 4, wherein the on-board electronic component is a connection portion to which a power supply line can be detachably connected.

12. The on-board update system according claim 2, wherein the on-board update apparatus includes an acquisition unit configured to acquire a detection result of the detection unit, and the notification unit.

13. The on-board update system according claim 3, wherein the on-board update apparatus includes an acquisition unit configured to acquire a detection result of the detection unit, and the notification unit.

14. The on-board update system according claim 4, wherein the on-board update apparatus includes an acquisition unit configured to acquire a detection result of the detection unit, and the notification unit.

15. The on-board update system according claim 5, wherein the on-board update apparatus includes an acquisition unit configured to acquire a detection result of the detection unit, and the notification unit.

16. The on-board update system according claim 6, wherein the on-board update apparatus includes an acquisition unit configured to acquire a detection result of the detection unit, and the notification unit.
